(19) United States
(12) Patent Application Publication
(10) Pub. No.: US 2009/0294939 A1
(43) Pub. Date: Dec. 3, 2009

(54) LEAD FRAME AND SEMICONDUCTOR DEVICE UTILIZING THE SAME

(75) Inventor: Kazuhiko Okishima, Ohtsu-Shi (JP)

Correspondence Address: YOUNG & THOMPSON, 209 Madison Street, Suite 500, ALEXANDRIA, VA, 22314, US

(73) Assignee: NEC ELECTRONICS CORPORATION, Kanagawa (JP)

(21) Appl. No.: 12/473,311

(22) Filed: May 28, 2009

(30) Foreign Application Priority Data
May 29, 2008 (JP) 2008-140850

(51) Int. Cl. H01L 23/495; H01L 21/50

(52) U.S. Cl. 257/676; 438/123; 257/E23.031; 257/E21.499

(57) ABSTRACT

A lead frame and semiconductor device providing improved bond strength from wave bonding such as of wires in lead frames manufactured with depressed inner leads. The lead frame comprises an outer lead, an inner lead, a step difference section formed between the outer lead and inner lead, and an extended section extending from the inner lead towards the outer lead side. The extended section is provided to be adjacent to the step difference section. An acceptor clamp jig set on the lead frame includes a body, an inner lead support section and extended section support section respectively corresponding to the outer lead, the inner lead and the extended section. The outer lead is pressed from above by a retainer clamp jig. The extended section of the inner lead and the extension support section of the acceptor clamp jig prevent the tip of the inner lead from floating upward by acting together to accept and resist the tensile stress applied on the step difference section of the lead. Ultrasonic waves are in this way applied more efficiently and ultrasonic wave loss in the bond part between the inner lead and the wire is reduced.

### CROSS-REFERENCE TO RELATED APPLICATIONS

The application is based upon, claims the benefit of priority of, and incorporates by reference the contents of Japanese Patent Application No. 2008-140850 filed on May 29, 2008.

### BACKGROUND

1. Field of the Invention

The present invention relates to a lead frame and a semiconductor device, and relates in particular to a lead frame possessing improved joint strength for ultrasonic wave bonding and a semiconductor utilizing that lead frame.

2. Description of Related Art

The lead frame utilized for manufacturing semiconductor devices is sometimes formed with a difference in height between the island and inner lead by forming the leads in a depress state with the aim of easily connecting the inner leads and the surface electrodes of the semiconductor chip with bonding wire and preventing problems such edge-touching of the wires.

FIG. 6 is a schematic perspective view of the semiconductor device shown in FIG. 1 of Japanese Unexamined Patent Application Publication No. 2000-49184 and its counterpart U.S. Pat. No. 6,307,272 B1. The surface electrodes 11, 12 are formed on the surface of the semiconductor chip 7, and are bonded to the inner lead 20 by way of the bonding wire 14. There is a step difference between the island 13 and the inner lead 20. The inner lead 20 connects to the outer lead 5 and a step difference section (depressed section) is formed along the outer lead 5.

FIG. 7 shows the technology of the prior art for clamping the lead frame during wire bonding when utilizing a lead frame where the leads were formed with depress. FIG. 7 is a cross sectional view of the lead frame retainer device shown in FIG. 2 of Japanese Unexamined Patent Application Publication No. Hei 7 (1995)-142529. A protrusion 104 is formed on a heater block piece 101. An island A1 makes direct contact with the heater block 101, and an inner lead A2 makes direct contact with the protrusion 104. The inner lead A2 is pressed against and clamped by a presser section 107 on the bottom surface of the presser piece 105. The inner lead A2 is in this way pressed to the protrusion 104 of heater block 101, and the ultrasonic waves applied during wire bonding can be efficiently conveyed with no loss to achieve satisfactory bonding.

FIG. 8 shows another example of the technology of the prior art. FIG. 8 is a cross sectional, view of the lead frame retainer device shown in FIG. 1(c) of Japanese Unexamined Patent Application Publication No. 2006-173284. In addition to a step difference section (depressed section) formed between the outer lead 212a and the island 209a where the semiconductor chip 215 is mounted, the lead frame 204 shown in FIG. 8, also includes a step difference section formed between the inner lead 209b and the outer lead 212b. The island 209a and the inner lead 203b are in this case clamped while set on the acceptor clamp jig 202, and the outer leads 212a and 212b are depressed by the retainer clamp jig 203.

### SUMMARY

The present inventor has realized that floating of the inner lead was occurring in these examples of the prior art. FIG. 9A, FIG. 9B and FIG. 9C are drawings of a lead frame 30 where a step difference section, (depressed section) 33 is formed between the outer lead 31 and the inner lead 32, and that describe the problem based on the knowledge of the present inventor. FIG. 9A is an upper surface diagrammatic plan view drawing of the state where the inner lead 32 is installed on an inner lead support piece 35a of the acceptor clamp jig 35. FIG. 9B is a diagrammatic cross sectional view taken along lines D-D of FIG. 9A. In order for a lead frame 30 with this type of structure to prevent the entire inner lead from floating during clamping, the inner lead support piece 35a supporting the inner lead 32, sets the acceptor clamp jig 35 at a height greater than the amount of upward-depress of the inner lead 32. In the state shown in FIG. 9A and FIG. 9B, the inner lead 32 of lead frame 30 has not yet been set on the inner lead support piece 35a of acceptor clamp jig 35.

However, the following problems occur when the lead frame 30 is clamped. Namely, when a pressing force F1 for clamping is applied to the outer lead 31 by the retainer clamp jig 36, a tensile stress F2 as shown in FIG. 9C, acts on the step difference section 33 to in this way generate a stress along the F3 direction so as to raise the tip 32b of the inner lead 32, and cause the tip 32b of that inner lead 32 to float upwards. Consequently, a loss of ultrasonic waves occurs in the joint between the inner lead 32 and the wire or bump during ultrasonic bonding such as of wires or bumps, so that the efficiency at which the ultrasonic waves are applied becomes worse and the joint strength deteriorates.

The lead frame of one aspect of the present invention comprises an outer lead, an inner lead, a step difference section (depressed section) formed between the outer lead and the inner lead, and an extended section extending from the inner lead toward the outer lead side. The extended section is provided to be adjacent to the step difference section.

A semiconductor device of another aspect of the present invention includes a semiconductor chip wire-bonded to the inner lead of the above mentioned lead frame.

A manufacturing method for a semiconductor device of still another aspect of the present invention sets the lead frame on an acceptor clamp jig including a body, an inner lead support piece, and an extended section support piece that respectively correspond to the outer lead, inner lead, and extended section; clamps the outer lead to the by using the retainer clamp jig, and ultrasonically bonds a wire to the inner lead.

According to an embodiment of the present invention, the tip of the inner lead can be prevented from floating upward, because the mutual action of the extended section and extended section support piece act to receive and resist the tensile stress during clamping, since an extended, section is integrally extended from the inner lead toward the outer lead side and the bottom surface of this extended section is supported by the acceptor clamp jig even if the tensile stress pulls on the step during clamping of the outer lead. A drop in bonding strength can in this way be reduced during ultrasonic bonding of wires and bumps, since the ultrasonic waves are efficiently applied with no ultrasonic wave loss occurring in the joint or bond between the inner lead and wire or bump, etc.

At least one extended section is formed between the step difference section connecting the inner lead and the outer lead. A plurality of extended sections may be formed sandwiching the step difference section. The extended section, preferably extends horizontally towards the inner lead. Though there are no particular restrictions on the shape, dimensions, or quantity of the extended sections, an extended section that is too short may fail to prevent upward floating of the inner lead tip that occurs due to tensile stress applied on the step difference section during clamping.

The extended sect ion may also preferably include a downward extended section extending downward from the tip of the extended section to the height of the outer lead bottom surface. The downward extended section may be formed perpendicularly, or may be formed facing obliquely.

### BRIEF DESCRIPTION OF THE DRAWINGS

The above and other objects, advantages and features of the present invention will become more apparent from the following description of certain preferred embodiments taken in conjunction with the accompanying drawings in which:

FIG. 1 is a fragmentary bird's eye view of the lead frame 40 in the first embodiment of the present invention;

FIG. 2 is a fragmentary bird's eye view showing the lead frame 40 of FIG. 1 mounted on the acceptor clamp jig 35;

FIG. 3A is a diagrammatic plan view of the acceptor clamp jig 35 and the lead frame 40 shown in FIG. 1;

FIG. 3B is a diagrammatic cross sectional view taken along lines C-C of FIG. 3A;

FIG. 3C is a diagrammatic cross sectional view during clamping of the applicable lead frame 40 by the retainer clamp jig 36;

FIG. 4 is a plan view of the lead frame 40 of the first embodiment of the present invention;

FIG. 5A is a fragmentary plan view showing the state where the semiconductor chip 37 is mounted on the island 38 of the lead frame 40 of the first embodiment of the present invention;

FIG. 5B is a cross sectional view taken along lines A-A of FIG. 5A;

FIG. 5C is a cross sectional view taken along lines B-B of FIG. 5A;

FIG. 6 is a schematic perspective view of the semiconductor device of the prior art;

FIG. 7 is a cross sectional view of the lead frame retainer device of another example of the prior art;

FIG. 8 is a cross sectional view of the lead frame retainer device of still another example of the prior art;

FIG. 9A through FIG. 9C are diagrammatic view for describing the problem based on the knowledge of the present inventor; in which

FIG. 9A is a diagrammatic plan view showing the state; where the inner lead 32 is mounted on the inner lead support piece 35a of acceptor clamp jig 35;

FIG. 9B is a diagrammatic cross sectional view taken along lines D-D of FIG. 9A; and

FIG. 9C is a diagrammatic cross sectional view showing the state where the outer lead 31 is pressed by the retainer clamp jig 36.

### DETAILED DESCRIPTION OF THE PREFERRED EMBODIMENTS

The present invention will now be described herein with reference to the illustrative embodiments. Those skilled in the art will recognize that many alternative embodiments can be rendered by using the teachings of the present invention, and that the invention is not limited to the embodiments illustrated for descriptive purposes.

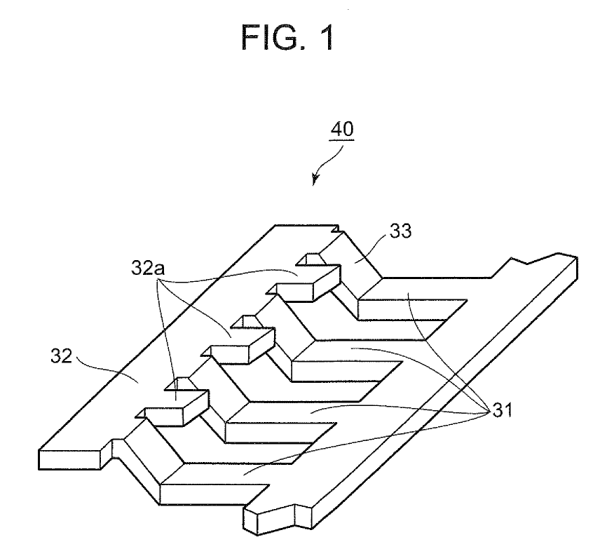

FIG. 1 is a fragmentary bird's eye view of the lead frame 40 in the first embodiment of this invention. This lead frame 40 includes an inner lead 32 depressed upwards from the outer lead 31. Namely, a step difference section (depressed section) 33 is formed between the outer lead 31 and the inner lead 32. A section of the inner lead 32 Includes a plurality of extended sections 32a extending towards the outer lead 31 side. The extended section 32a is provided to be adjacent to the step difference section 33. Forming the extended section 32a between two of the step difference sections 33 is advantageous. Forming this extended section 32a allows resisting the tensile stress applied to the step difference section 33 when the outer lead 31 is pressed, and stops the inner lead 32 from floating upwards.

The shape of the extended section 32a need not necessarily be the rectangular shape as shown in FIG. 1. Moreover, there are no particular restrictions on the size of the extended section 32a. A longer extended section 32a extending from the inner lead 32 is preferable in terms of resistance to the tensile stress but a less long extended section 32a is better for avoiding interference with other members such as the retainer clamp described later on. An extended section 32a length equal to approximately the horizontal projection of step difference section 33 is preferable. There are also no particular restrictions on the number of extended sections 32a but one extended section 32a can easily be formed between each of the step difference sections 33 as shown in FIG. 1, and is also preferable for allowing each step difference section 33 to resist the tensile stress. If only forming one step difference section 33, then forming an extended section 32a on both sides of that step difference section is advisable.

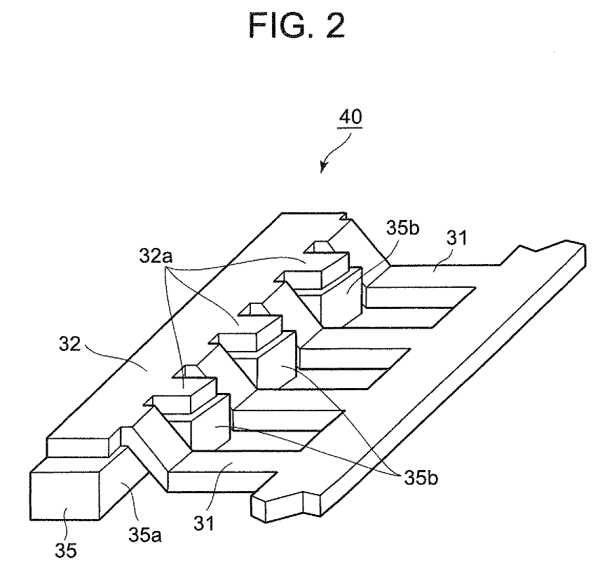

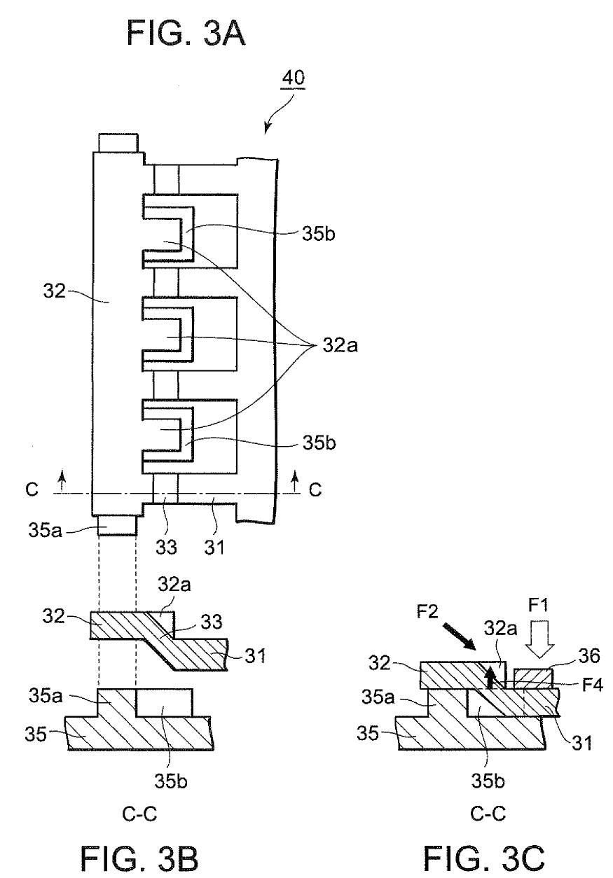

FIG. 2 is a fragmentary bird's eye view showing the lead frame 40 of FIG. 1 mounted on the acceptor clamp jig 35. The acceptor clamp jig 35 includes an inner lead support piece 35a supporting the bottom surface of the inner lead 32, and an extended section support piece 35b supporting the bottom surface of the extended section 32a which are formed on the body (refer to FIG. 3). The extended section support piece 35b is mounted so as to match each of the extended sections 32a and is also formed so as to project outwards from the inner lead support piece 35a. To make FIG. 2 easier to understand, the body of the acceptor clamp jig 35 is not shown and only the inner lead support section 35a and the extended section support piece 35b are shown.

The effect rendered by the present invention is described next while referring to FIG. 3. FIG. 3A is a diagrammatic plan view of the acceptor clamp jig 35 and the lead frame 40. FIG. 3B is a cross sectional view taken along lines C-C of FIG. 3A. FIG. 3A and FIG. 3B show the state where the lead frame 40 has not yet been set on the acceptor clamp jig 35. To make the drawing easy to understand, the diagrammatic plan view of FIG. 3A shows only the inner lead support section 35a and the extended section support piece 35b on the acceptor clamp jig 35. FIG. 3C is a diagrammatic cross sectional view taken along lines C-C of FIG. 3A showing the lead frame 40 set on the acceptor clamp jig 35, and further showing the state where clamped by the pressing force F1 of the retainer clamp jig 36.

As shown in FIG. 3C, the bottom surface of the inner lead 32 makes direct contact with the inner support piece 35a, and the bottom surface of the outer lead 31 makes direct contact with the body of the acceptor clamp jig 35. The bottom surface of the extended section 32a makes direct contact with the extended section support piece 35b. The extended section support pieces 35b support their corresponding extended sections 32a at the bottom to generate a support force F4. This support force F4 allows the extended section 32a to accept a tensile stress F2 genera, ted when the lead frame 40 is depressed by the retainer clamp jig 36, and that acts to pull downward on the step difference section 33. The support force F4 in this way prevents the tip of inner lead 32 from floating upward.

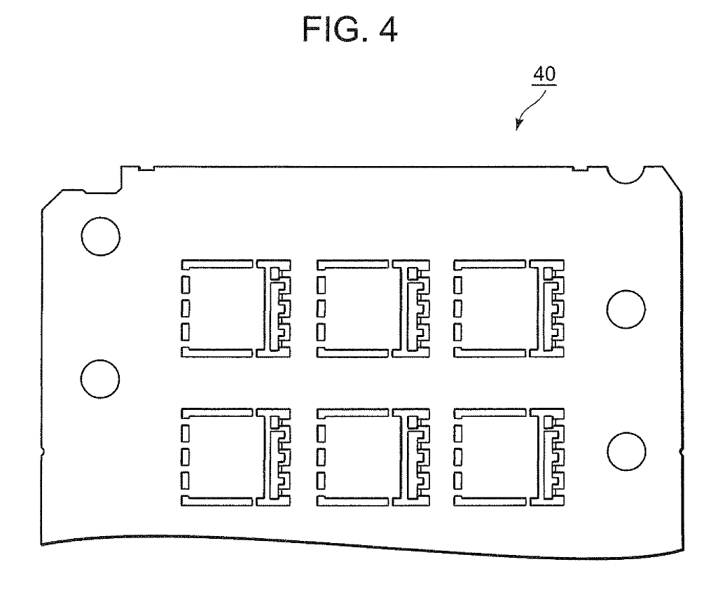

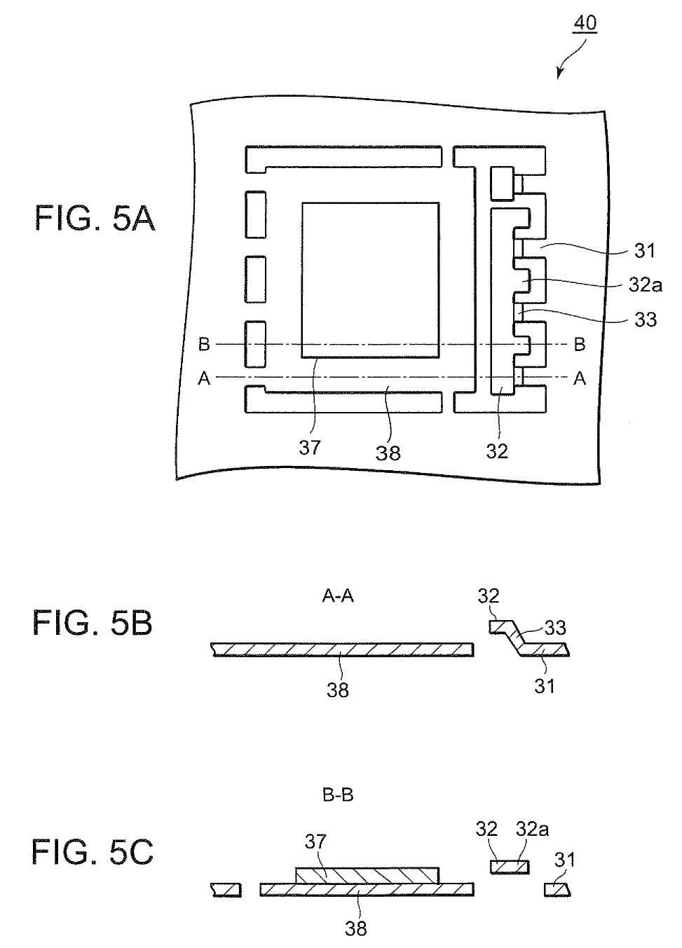

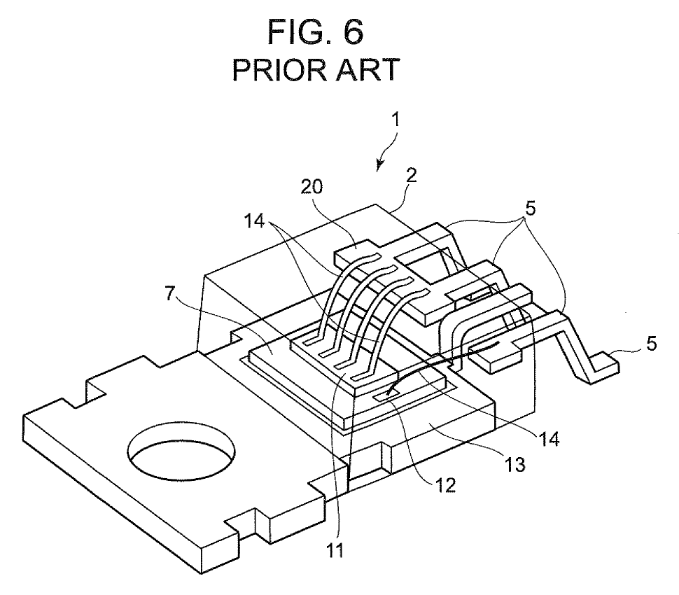

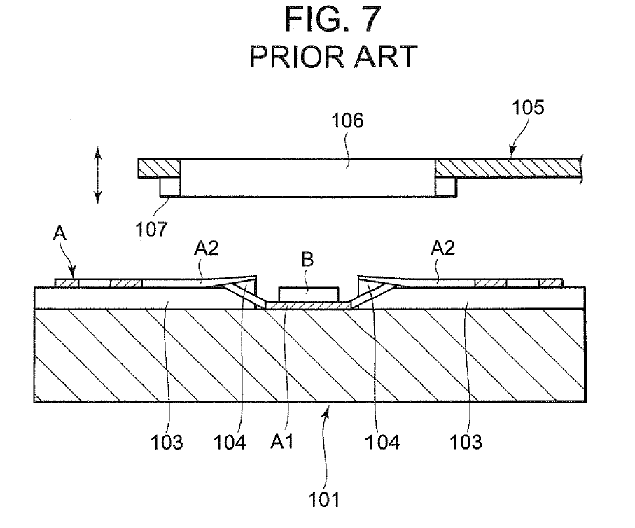

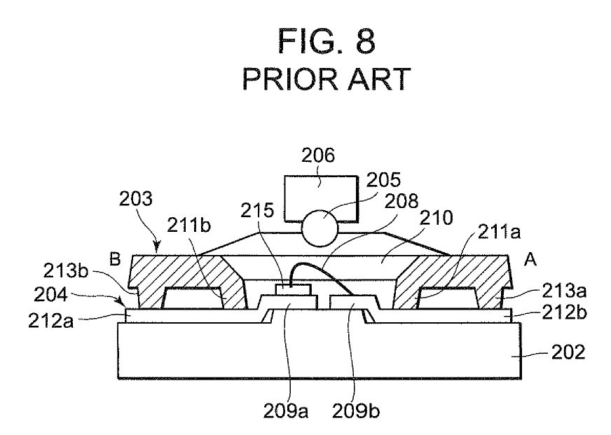

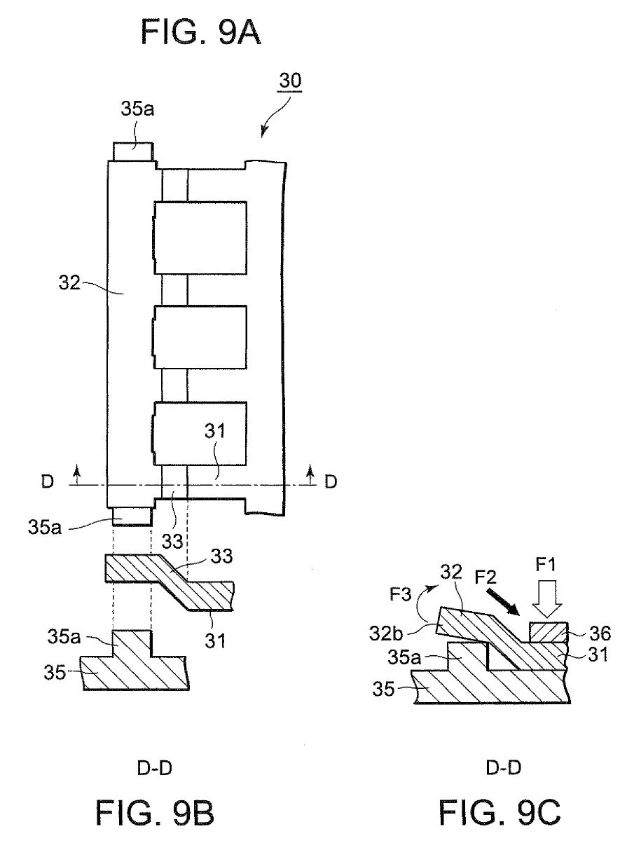

FIG. 4 is a plan view showing a specific example of the lead frame 40 of the present invention structured to allow mounting multiple semiconductor chips in a matrix. FIG. 5A is a fragmentary plan view showing the state where the semiconductor chip 37 is mounted on the island 38 of the lead frame 40. FIG. 5B is a cross sectional view taken along lines A-A of FIG. 5A, and shows a cross section of the section where the inner lead 32 is connected to the outer lead 31 by the step difference section 33. The FIG. 5C is a cross sectional view taken along lines B-B of FIG. 5C, and shows a cross section of the section containing the inner lead 32 and the extended section 32a. The side face of another part of the lead frame 40 and the bonding wire is omitted from the drawings in FIG. 5A through FIG. 5C.

A second retainer clamp jig (not shown in drawing) for depressing the extended section 32a, may also be used in addition to the retainer clamp jig 36 that depresses the outer lead 31 as shown in FIG. 3A through FIG. 3C. In this way, even if a depressing amount that is larger than the height, of the acceptor clamp jig 35 occurs due to variations occurring in the manufacture of the lead frame 40, the depressing of the extended section 32a by the second retainer clamp jig along with the retainer clamp jig 36 acts to attach the inner lead 32 firmly to the inner lead support piece 35a of the acceptor clamp jig so that a satisfactory joint strength is obtained during ultrasonic wave bonding of wires and bumps because the ultrasonic waves are efficiently applied with no loss of ultrasonic waves in the section joining the inner lead to wires or bumps, etc.

Though not shown in the drawing, the tip of the extended section 32a can further extend downward to the bottom surface of the outer lead, so as to make contact with the acceptor clamp jig 35. The extended section 32a itself can in this way be supported by the acceptor clamp jig 35 even, without forming an extended section support piece 35b for supporting the extended section 32a, and the same effect is achieved.

Moreover, the lead frame formed with the leads shown in FIG. 1 and the lead frame formed with islands may together form the same (single) lead frame, however mutual, separate lead frames may also be used.

It is apparent that the present invention is not limited to the above embodiments and may be modified and changed without departing from the spirit and the scope of the invention.

What is claimed is:

1. A lead frame comprising:
an outer lead;
an inner lead;
a step difference section formed between the outer lead and the inner lead; and
an extended section extending from the inner lead toward the outer lead side and provided to be adjacent to the step difference section.

2. The lead frame according to claim 1, wherein
the lead frame comprises a plurality of step difference sections, and
the extended section is sandwiched between two of the plurality of step difference sections.

3. The lead frame according to claim 1, wherein
the lead frame comprises a plurality of extended sections, and
the step difference section is sandwiched between two of the plurality of extended sections.

4. The lead frame according to claim 1, wherein
the extended section is horizontal relative to the inner lead.

5. The lead frame according to claim 1, wherein
the extended section includes a downward extended section, extending further downward from the tip of one extended section to the height of the outer lead bottom surface.

6. The lead frame according to claim 1, further comprising:
a semiconductor chip wire-bonded to the inner lead.

7. The lead frame according to claim 6, further comprising:
an island,
wherein the semiconductor chip is mounted to the island.

8. A manufacturing method for lead frame which is mounted a semiconductor chip thereon comprising:
preparing a lead frame including an outer lead, an inner lead, a step difference section formed between the outer lead and the inner lead, and an extended section extending from the inner lead toward the outer lead side to be provided adjacent to the step difference section;
mounting of the lead frame on an acceptor clamp jig, the acceptor clamp jig including a body, an inner lead support piece and an extension support piece respectively corresponding to the outer lead, the inner lead and the extended section;
clamping the outer lead to the body by using the retainer clamp jig;
ultrasonically bonding a wire to the inner lead.
